(19) United States
(12) Patent Application Publication
(10) Pub. No.: US 2009/0050195 A1
(43) Pub. Date: Feb. 26, 2009

(54) SOLAR CELL MODULE

(75) Inventor: Satoru Ogasahara, Kobe-shi (JP)

Correspondence Address: DITTHAVONG MORI & STEINER, P.C., 918 Prince St., Alexandria, VA, 22314, US

(73) Assignee: Sanyo Electric Co., Ltd., Moriguchi-shi (JP)

(21) Appl. No.: 12/192,511

(22) Filed: Aug. 15, 2008

(30) Foreign Application Priority Data
Aug. 21, 2007 (JP) 2007-214915
Jun. 26, 2008 (JP) 2008-167196

(51) Int. Cl. H01L 31/048

(52) U.S. Cl. 136/251

(57) ABSTRACT

This solar cell module includes a platelike solar cell panel including a solar cell element, a frame body including a groove portion into which the outer periphery of the solar cell panel is fitted, a sealant so provided as to fill up a space between the outer periphery of the solar cell panel and the groove portion of the frame body and a spacer member, made of a material having a smaller coefficient of elasticity than the material for a photoreceiving side of the solar cell panel and the material for the frame body, provided on a region where the photoreceiving side or a rear side of the outer periphery of the solar cell panel and the groove portion of the frame body are opposed to each other.

### CROSS-REFERENCE TO RELATED APPLICATIONS

The priority application number JP2007-214915, solar cell module, Aug. 21, 2007, Satoru Ogasahara, and JP2008-167196, solar cell module, Jun. 26, 2008, Satoru Ogasahara upon which this patent application is based are hereby incorporated by reference.

### BACKGROUND OF THE INVENTION

1. Field of the Invention

The present invention relates to a solar cell module, and more particularly, it relates to a solar cell module comprising a frame body into which the outer periphery of a platelike solar cell panel is fitted.

2. Description of the Background Art

A solar cell module comprising a frame body into which the outer periphery of a platelike solar cell panel is fitted is known in general. In an exemplary conventional solar cell module, a retaining frame (outer frame) of aluminum integrally provided with a groove portion retains a panel body by vertically holding the outer periphery of a solar cell panel. In this solar cell module, the outer periphery of the solar cell panel is fitted into the groove portion of the retaining frame through an adhesive (sealant) having fluidity in close contact with the adhesive, so that the retaining frame retains the panel body.

If a load is applied to the solar cell panel of the aforementioned solar cell module due to the own weight of the panel body or bad weather conditions (strong wind etc.) in an outdoor location, however, the panel body is deflected, and stress is concentrated on the outer periphery of the solar cell panel vertically held by the retaining frame. Particularly in a thin film solar cell panel having a photoreceiving surface made of unreinforced white plate glass, the glass surface is broken due to cracking resulting from stress concentration on the outer periphery of the glass surface. Therefore, the strength of the panel body including the glass surface (photoreceiving surface) cannot be sufficiently maintained.

In another exemplary conventional solar cell module, a metal outer frame having an engaging portion and a plurality of projecting portions integrally formed on the engaging portion retains a solar cell panel body by vertically holding a portion around the outer periphery of a solar cell panel by the projecting portions. In this solar cell module, the outer periphery of the solar cell panel is fitted into the engaging portion of the outer frame through a sealant having fluidity in close contact with the sealant, so that the outer frame retains the solar cell panel body.

In the aforementioned solar cell module, however, the projecting portions of the same material as the outer frame hold the portion around the outer periphery of the solar cell panel. If a load is applied to the solar cell panel due to the own weight of the panel body or bad weather conditions (strong wind etc.) in an outdoor location, therefore, the panel body is deflected, and stress is concentrated on the outer periphery of the solar cell panel vertically held by the projecting portions. Particularly in a thin film solar cell panel having a photoreceiving surface made of unreinforced white plate glass, the glass surface is broken due to cracking resulting from stress concentration on the outer periphery of the glass surface. Therefore, the strength of the panel body including the photoreceiving surface (glass surface) cannot be sufficiently maintained.

In an exemplary conventional thin film solar cell module, an aluminum frame (support member) integrally provided with a groove portion retains a panel body by vertically holding a portion around the outer periphery (edge) of a solar cell panel. In this thin film solar cell module, a sealant of rubber is so mounted as to cover the portion around the outer periphery (edge) of the solar cell panel with a prescribed thickness, and the panel body is fitted into the groove portion of the frame from above the sealant through an insulator spacer, so that the frame retains the panel body. The insulator spacer is so provided as to vertically hold the panel body on a region closer to the center of the panel than the outer periphery (edge) of the solar cell panel, and hence a clearance is provided between the outer surface of the sealant covering the outer periphery (edge) of the solar cell panel and the groove portion of the frame.

In the aforementioned thin film solar cell module, however, the sealant of rubber covers only the portion around the outer periphery (edge) of the solar cell panel with the prescribed thickness, while the clearance is provided between the outer surface of the sealant and the groove portion of the frame. When the panel body is deflected due to wind and rain or the like, therefore, rainwater may penetrate into the clearance. In this case, water resistance and water stoppability of the thin film solar cell module are disadvantageously reduced.

### SUMMARY OF THE INVENTION

A solar cell module according to an aspect of the present invention comprises a platelike solar cell panel including a solar cell element, a frame body including a groove portion into which the outer periphery of the solar cell panel is fitted, a sealant so provided as to fill up a space between the outer periphery of the solar cell panel and the groove portion of the frame body and a spacer member, made of a material having a smaller coefficient of elasticity than the material for a photoreceiving side of the solar cell panel and the material for the frame body, provided on a region where the photoreceiving side or a rear side of the outer periphery of the solar cell panel and the groove portion of said frame body are opposed to each other.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view showing the overall structure of a thin film solar cell module according to an embodiment of the present invention;

FIG. 2 is a sectional view taken along the line 200-200 in FIG. 1;

FIG. 3 is a plan view for illustrating the structure of the thin film solar cell module according to the embodiment shown in FIG. 1;

FIGS. 4 to 7 are diagrams for illustrating a manufacturing process for the thin film solar cell module according to the embodiment shown in FIG. 1;

FIG. 8 is a diagram for illustrating a first modification of the thin film solar cell module according to the embodiment shown in FIG. 1; and

FIG. 9 is a diagram for illustrating a second modification of the thin film solar cell module according to the embodiment shown in FIG. 1.

### DESCRIPTION OF THE PREFERRED EMBODIMENTS

An embodiment of the present invention is now described with reference to the drawings.

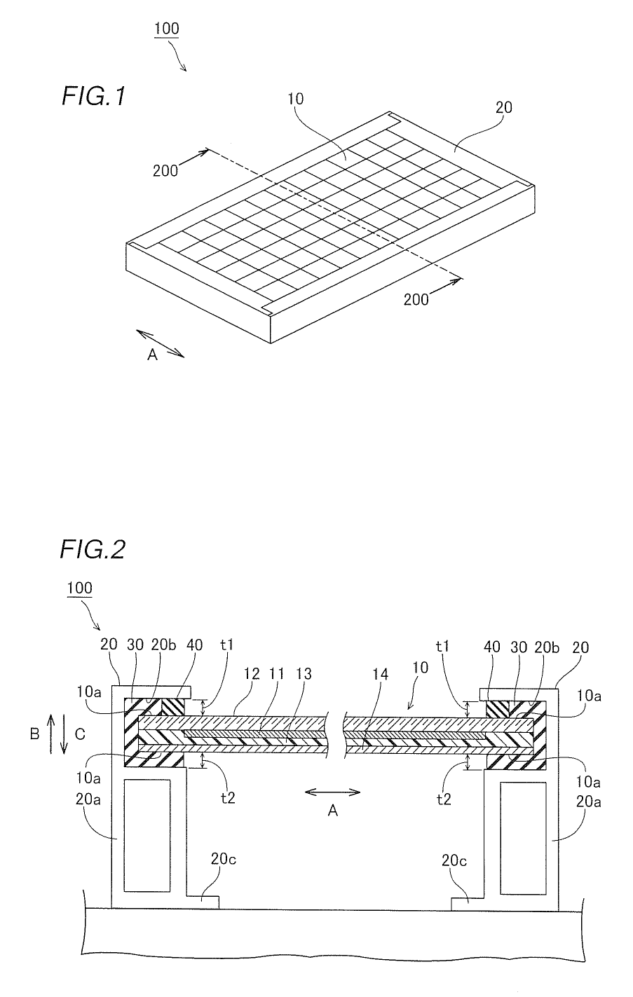

First, the structure of a thin film solar cell module 100 according to the embodiment of the present invention is described with reference to FIGS. 1 to 3. This embodiment of the present invention is applied to the thin film solar cell module 100 employed as an exemplary solar cell module.

As shown in FIG. 1, the thin film solar cell module 100 according to the embodiment of the present invention comprises a solar cell panel 10 and a frame body 20 enclosing the four sides of the outer periphery of the solar cell panel 10. As shown in FIG. 2, the solar cell panel 10 has a structure obtained by holding a solar cell layer 11 between a white plate glass layer 12 provided on the upper surface (photoreceiving side) of the solar cell layer 11 and a sealing resin layer 13 of EVA (ethylene vinyl acetate) resin provided on the lower surface (rear side) thereof and stacking a protective back sheet 14 on the lower surface of the sealing resin layer 13. Thus, the thin film solar cell module 100 has a thickness of about 4.5 mm. The solar cell layer 11, the with plate glass layer 12 and the back sheet 14 are examples of the “solar cell element”, the “material for a photoreceiving side” and the “material for a rear side” in the present invention respectively.

The frame body 20 is so formed as to have a sectional shape shown in FIG. 2 by extruding an aluminum material. More specifically, the frame body 20 has a structure obtained by integrally forming a hollow body portion 20a, a substantially U-shaped groove portion 20b provided on an upper part of the body portion 20a for holding and retaining the outer periphery 10a of the solar cell panel 10 and a leg 20c for fixing the frame body 20 to a base (not shown) or the like. As shown in FIG. 2, the vertical width (along arrows B and C) of the groove portion 20b is about 7.5 nm. According to this embodiment, the upper surface (photoreceiving surface) and the lower surface (rear surface) of the solar cell panel 10 and the surfaces of the groove portion 20b of the frame body 20 opposed to these upper and lower surfaces respectively are substantially parallel to each other.

According to this embodiment, a sealant 30 prepared from silicone resin or the like is injected into the thin film solar cell module 100 to have a substantially U-shaped section along the inner surface of the groove portion 20b in order to fill up the space between the outer periphery 10a of the solar cell panel 10 and the groove portion 20b of the frame body 20, as shown in FIG. 2. Thus, according to this embodiment, the sealant 30 is so charged as to enclose a surface (upper surface of the white plate glass layer 12) on the photoreceiving side of the outer periphery 10a of the solar cell panel 10, another surface (lower surface of the back sheet 14) on the rear side of the outer periphery 10a of the solar cell panel 10 and end faces of the solar cell panel 10. Substantially the overall surface of the sealant 30 opposed to the groove portion 20b is in contact with the inner surface of the groove portion 20b of the frame body 20. The sealant 30 is sealed with a spacer member 40 described later on the photoreceiving side of the solar cell panel 10, and exposed outward from the rear surface, provided with no spacer member 40, of the solar cell panel 10. Therefore, the U-shaped sealant 30 is so arranged that the upper end face (photoreceiving side) thereof is in contact with the spacer member 40. The upper end face of the sealant 30 is an example of the “first end face” in the present invention.

The sealant 30 may alternatively be prepared from urethane resin or the like, for example, so far as the material is solidified with time. Also the frame body 20 may alternatively be made of another metal other than aluminum.

According to this embodiment, the spacer member 40 (having a thickness of about 1.5 mm and a width of about 2 mm along arrow A (see FIG. 2)) made of rubber or the like is provided on the region between the surface of the outer periphery 10a of the solar cell panel 10 on the side of the white plate glass layer 12 (photoreceiving side) and the groove portion 20b of the frame body 20 opposed to the outer periphery 10a. The spacer member 40 is so formed that the coefficient of elasticity (about 3×10⁶ Pa to about 1×10⁷ Pa) thereof is smaller than the coefficient of elasticity (about 7.16×10¹⁰ Pa) of the white plate glass layer 12 and the coefficient of elasticity (about 7.03×10¹⁰ Pa) of the frame body 20. The lower limit of the coefficient of elasticity of the spacer member 40 can be reduced to such a degree that the spacer member 40 is not substantially deformed by the own weight (varied with the panel size) of the solar cell panel 10.

When the solar cell panel 10 has a size of 1.1 m (length) by 1.2 m (width) by 4.5 mm (thickness) and the aforementioned spacer member 40 (having the thickness of about 1.5 mm and the width of about 2 mm) is provided along the overall periphery of the solar cell panel 10, for example, the spacer member 40 is deformed only by about 0.006 mm at the maximum in the thickness direction due to the own weight (about 13 kg) of the solar cell panel 10. In this case, therefore, the spacer member 40 is regarded as substantially undeformed in practice.

The aforementioned rubber employed as the material for the spacer member 40 denotes general rubber such as synthetic (isoprene) rubber, styrene rubber, butadiene rubber, urethane rubber, fluororubber, butyl rubber or silicone. Alternatively, the spacer member 40 may be made of another resin material having a smaller coefficient of elasticity than aluminum, cellulose acetate (coefficient of elasticity: about 1.9×10⁹ Pa), phenolic resin (coefficient of elasticity: about 8.0×10⁹ Pa), epoxy resin (coefficient of elasticity: about 2.5×10⁹ Pa), acrylic foam (coefficient of elasticity: about 7.0×10⁷ Pa) or cork, for example.

According to this embodiment, the spacer member 40 is so provided as to substantially come into contact with the surface of the white plate glass layer 12 and the surface of the groove portion 20b of the frame member 20 through an adhesive (not shown), as shown in FIG. 2. Further, the spacer member 40 is arranged on a region of the groove portion 20b inward beyond an opening end face thereof. In addition, the spacer member 40 is so provided as to fill up the space between the surface (surface of the white plate glass layer 12) on the photoreceiving side of the solar cell panel 10 and the surface of the groove portion 20b of the frame member 20 opposed to the surface on the photoreceiving side. Thus, the spacer member 40 seals the sealant 30 on the photoreceiving side of the solar cell panel 10. On the other hand, the rear side (surface of the back sheet 14) of the solar cell panel 10 provided with no spacer member 40 is filled up with the sealant 30 up to a region corresponding to the position where the spacer member 40 is arranged.

According to this embodiment, the sealant 30 is so formed that the thickness t1 of the portion charged into the space between the surface (photoreceiving surface) of the white plate glass layer 12 of the solar cell panel 10 and the surface of the groove portion 20b of the frame member 20 opposed to the surface of the white plate glass layer 12 and the thickness t2 of the portion charged into the space between the surface of the back sheet 14 of the solar cell panel 10 and the surface of the groove portion 20b of the frame body 20 opposed to the surface of the back sheet 14 are substantially identical to each other (about 1.5 mm), as shown in FIG. 2. The thicknesses t1 and t2 are substantially identical to the thickness (about 1.5 mm) of the spacer member 40. In other words, the spacer member 40 is so formed that the thickness thereof is substantially equal to the interval (t1) between the surface on the photoreceiving side of the solar cell panel 10 and the surface of the groove portion 20b of the frame body 20 opposed to the surface on the photoreceiving side and the interval (t2) between the surface on the rear side of the solar cell panel 10 and the surface of the groove portion 20b of the frame body 20 opposed to the surface on the rear side.

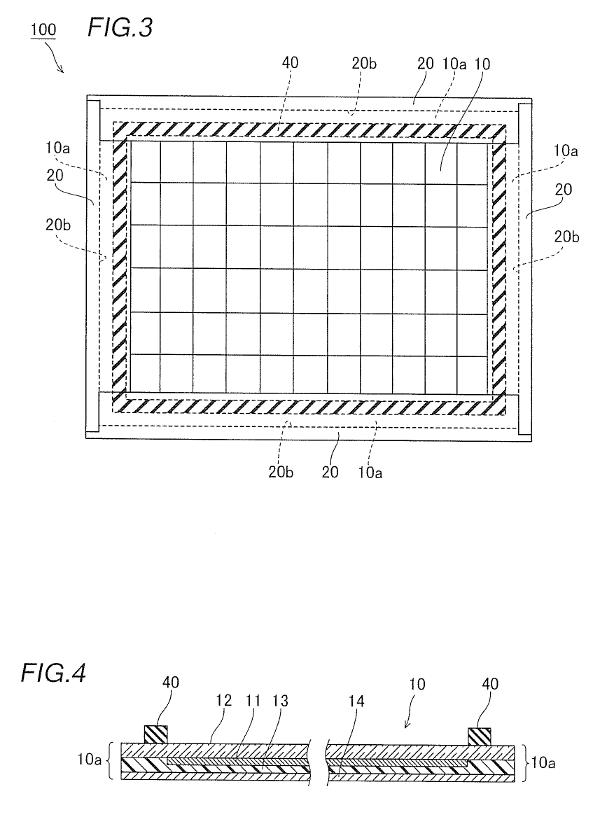

According to this embodiment, the spacer member 40 is so circumferentially arranged as to enclose the outer periphery 10a of the solar cell panel 10 along the groove portion 20b of the frame member 20 in plan view, as shown in FIG. 3. Further, the spacer member 40 is arranged on the overall periphery along the groove portion 20b of the frame body 20 in a substantially jointless manner. According to this embodiment, the spacer member 40 is arranged outside the region where the solar cell layer 11 is arranged. More specifically, the spacer member 40 is arranged on a region adjacent to the region where the solar cell layer 11 is arranged in plan view.

In the solar cell panel 10 (see FIG. 2), an insulating layer (not shown) is arranged under a solder-plated copper foil member (not shown) for extracting power from the solar cell layer 11 so that the solder-plated copper foil member is not electrically in contact with the cell, while the solder-plated copper foil member is drawn onto the back sheet 14 through a notch (not shown) provided in the sealing resin layer 13 (see FIG. 2) and the back sheet 14 (see FIG. 2).

The sealing resin layer 13 may alternatively be made of PVA (polyvinyl acetal) resin or silicone resin, in place of the aforementioned EVA (ethylene vinyl acetate) resin.

The back sheet 14 is constituted of a multilayer film of Tedler®/Al/Tedler® or the like. Tedler® is the registered trademark of a polyvinyl fluoride (PVF) film manufactured and sold by E.I. du Pont de Nemours and Company. The back sheet 14 may alternatively be constituted of a multilayer film of Tedler®/PET (polyethylene terephthalate) resin/Tedler® or a resin film coated with a layer of an inorganic compound such as SiO₂, in place of the aforementioned material.

A manufacturing process for the thin film solar cell module 100 according to the embodiment of the present invention is now described with reference to FIGS. 2 and 4 to 7.

First, the solar cell panel 10 is formed by a prescribed process, as shown in FIG. 4. Then, the spacer member 40 is mounted on a portion around the outer periphery 10a of the solar cell panel 10 on the side of the white plate glass layer 12 (photoreceiving side).

According to this embodiment, the spacer member 40 is arranged on the overall periphery of the portion around the outer periphery 10a of the solar cell panel 10 in a substantially jointless manner, as shown in FIG. 3.

Then, the frame body 20 is vertically inverted (so that the leg 20c is located upward), and a prescribed quantity of the sealant 30 prepared from silicone resin or the like having fluidity is injected into the groove portion 20b of the frame body 20, as shown in FIG. 5.

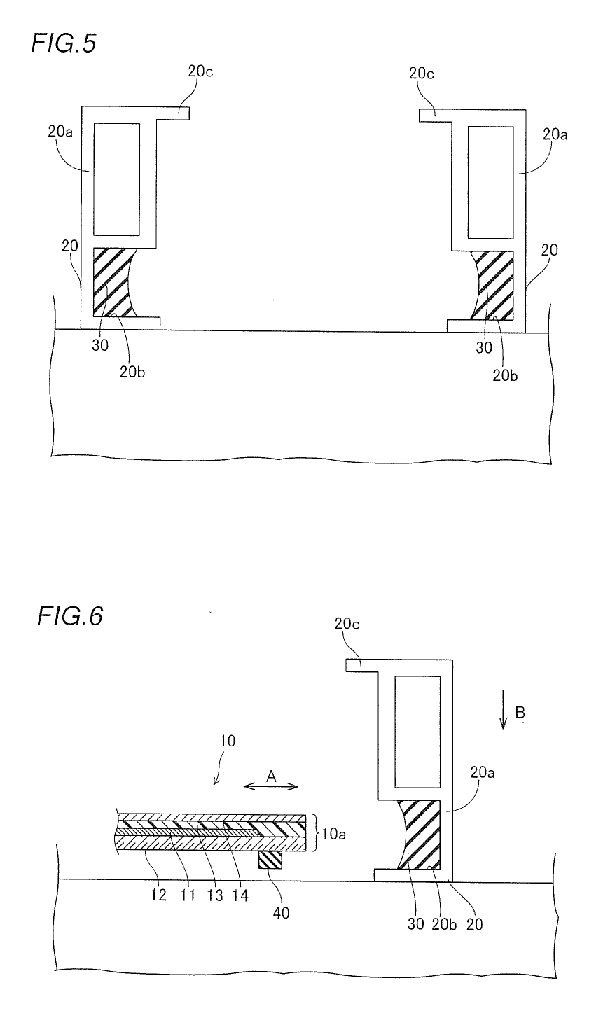

Then, the solar cell panel 10 is slid in the horizontal direction (along arrow A) and fitted into the groove portion 20b of the frame body 20 filled up with the sealant 30 while the side of the white plate glass layer 12 (photoreceiving side) of the solar cell panel 10 is directed downward, as shown in FIG. 6.

According to this embodiment, the solar cell panel 10 is slightly pressed in the vertical direction (along arrow B) to be fitted into the groove portion 20b of the frame body 20 so that the spacer member 40 previously mounted on the solar cell panel 10 comes into contact with the surface of the groove portion 20b of the frame body 20, as shown in FIG. 2. Thus, the sealant 30 having fluidity is deformed in response to the shapes of the solar cell panel 10 and the spacer member 40 combined with each other, to fill up the space between the outer periphery 10a of the solar cell panel 10 and the groove portion 20b of the frame member 20. At this time, the sealant 30 is so charged that the thickness t1 of the portion closer to the surface of the white plate glass layer 12 and the thickness t2 of the portion closer to the surface of the back sheet 14 are substantially identical to each other (about 1.5 mm), as shown in FIG. 2.

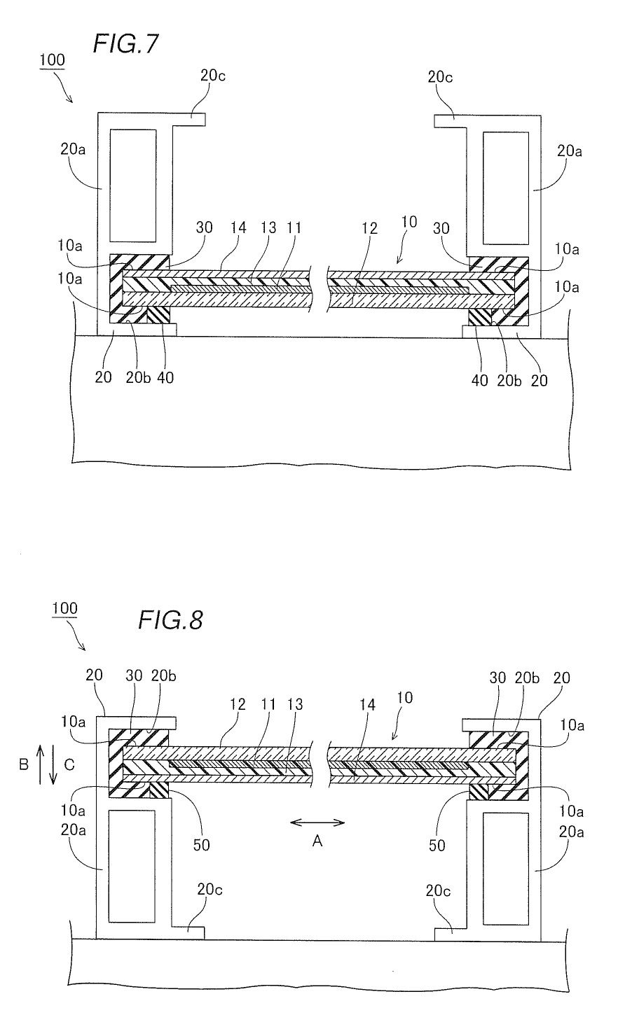

Thereafter the solar cell panel 10 and the frame body 20 are allowed to stand on a horizontal plane for a prescribed time while the side of the white plate glass layer 12 (photoreceiving side) of the solar cell panel 10 is directed downward, as shown in FIG. 7. Thus, the sealant 30 is solidified with time. At this time, the spacer member 40 is not substantially deformed by the own weight of the solar cell panel 10, due to the coefficient of elasticity thereof. Therefore, the sealant 30 is solidified with time while maintaining the shape obtained immediately after the solar cell panel 10 is fitted into the groove portion 20b.

The thin film solar cell module 100 according to the embodiment of the present invention is formed in the aforementioned manner.

According to this embodiment, as hereinabove described, the thin film solar cell module 100 comprises the sealant 30 so provided as to fill up the space between the outer periphery 10a of the solar cell panel 10 and the groove portion 20b of the frame body 20 so that the sealant 30 also closely fills up the clearance between the outer periphery 10a of the solar cell panel 10 and the groove portion 20b of the frame body 20, whereby rainwater or the like is inhibited from penetrating into the clearance. Thus, water resistance and water stoppability of the thin film solar cell module 100 can be prevented from reduction.

According to this embodiment, the thin film solar cell module 100 comprises the spacer member 40, made of the material having the smaller coefficient of elasticity than the material for the white plate glass layer 12 of the solar cell panel 10 and the material for the frame body 20, provided on the region where the side of the outer periphery 10a of the solar cell panel 10 closer to the white plate glass layer 12 (photoreceiving side) and the groove portion 20b of the frame body 20 are opposed to each other, whereby the spacer member 40, having the smaller coefficient of elasticity than the materials for the solar cell panel 10 and the frame body 20, provided on the region where the outer periphery 10a of the solar cell panel 10 and the groove portion 20b of the frame body 20 are opposed to each other serves as a buffer material against deformation of the solar cell panel 10 resulting from the own weight of the body of the solar cell panel 10 or bad weather conditions (strong wind etc.) in an outdoor location. In other words, deformation of the solar cell panel 10 does not directly act on the frame body 20, whereby the outer periphery 10a on the photoreceiving side can be prevented from cracking resulting from stress concentration even if the white plate glass layer 12 provided on the photoreceiving side is unreinforced, for example. Consequently, load resistance of the body of the solar cell panel 10 including the glass surface (photoreceiving surface) can be improved.

According to this embodiment, the thin film solar cell module 100 comprises the spacer member 40 on the region where the photoreceiving side (side of the white plate glass layer 12) of the outer periphery 10a of the solar cell panel 10 and the groove portion 20b of the frame body 20 are opposed to each other so that the thickness t1 of the portion of the sealant 30 charged into the space between the outer periphery 10a of the solar cell panel 10 and the groove portion 20b of the frame body 20 can be equalized with the thickness of the spacer member 40, whereby the sealant 30 can be formed in the constant thickness (t1). When the thickness of the spacer member 40 is simply set to a prescribed size, not only the thickness t1 of the portion of the sealant 30 filling up the space around the spacer member 40 provided on the region between the photoreceiving side (side of the white plate glass layer 12) of the solar cell panel 10 and the groove portion 20b of the frame body 20 but also the thickness t2 of the portion of the sealant 30 filling up the region between the rear side (side of the back sheet 14) of the solar cell panel 10 and the groove portion 20b of the frame body 20 are univocally decided. Thus, the thicknesses t1 and t2 of both of the portions of the sealant 30 charged into the photoreceiving side (side of the white plate glass layer 12) and the rear side (side of the back sheet 14) are simultaneously adjusted due to the spacer member 40 provided on one side (side of the white plate glass layer 12) in the thin film solar cell module 100.

According to this embodiment, the spacer member 40 is so arranged as to substantially come into contact with the portion around the outer periphery 10a on the photoreceiving side of the solar cell panel 10 and the surface of the groove portion 20b of the frame body 20 opposed to the portion around the outer periphery 10a on the photoreceiving side (side of the white plate glass layer 12) so that deformation of the solar cell panel 10 resulting from the own weight of the body of the solar cell panel 10 or bad weather conditions (strong wind etc.) in an outdoor location is directly transmitted to the spacer member 40, whereby the deformation of the solar cell panel 10 can be more reliably absorbed, and the strength on the photoreceiving side (side of the white plate glass layer 12) can be maintained. Further, the spacer member 40 is so arranged as to come into contact with the photoreceiving side (side of the white plate glass layer 12) for preventing the sealant 30 filling up the space between the outer periphery 10a of the solar cell panel 10 and the groove portion 20b of the frame body 20 from overreaching the spacer member 40 toward the photoreceiving side (side of the white plate glass layer 12), whereby no sealant 30 overreaching the spacer member 40 toward the side of the white plate glass layer 12 may be removed dissimilarly to a case where no spacer member 40 is arranged and the sealant 30 having fluidity protrudes toward the side of the white plate glass layer 12. Therefore, assembling operability of the thin film solar cell module 100 can be improved.

According to this embodiment, the thickness t1 of the portion of the sealant 30 filling up the space between the photoreceiving surface (white plate glass layer 12) of the solar cell panel 10 in the outer periphery 10a of the solar cell panel 10 and the surface of the groove portion 20b of the frame body 20 opposed to the photoreceiving surface and the thickness t2 of the portion of the sealant 30 filling up the space between the rear surface (back sheet 14) of the solar cell panel 10 in the outer periphery 10a of the solar cell panel 10 and the surface of the groove portion 20b of the frame body 20 opposed to the rear surface are substantially equalized with each other so that the thicknesses of the portions of the sealant 30 vertically in contact with the outer periphery 10a of the solar cell panel 10 and the surfaces of the groove portion 20b of the frame body 20 are substantially identical to each other. Whether external force is applied to the body of the solar cell panel 10 upward (along arrow in FIG. 2) or downward (along arrow C in FIG. 2), therefore, the sealant 30 can hold the solar cell panel 10 in substantially identical conditions regardless of the direction of the external force. Thus, the load resistance of the solar cell panel 10 can be more reliably improved.

According to this embodiment, as hereinabove described, the sealant 30 is sealed with the spacer member 40 on the photoreceiving side of the solar cell panel 10 and so formed as to be exposed outward from the rear surface, provided with no spacer member 40, of the solar cell panel 10, whereby the sealant 30 can be prevented from overreaching the spacer member 40 toward the photoreceiving side (side of the white plate glass layer 12) while the surplus of the sealant 30 injected into the groove portion 20b can protrude from the groove portion 20b on the rear side of the solar cell panel 10 when the solar cell panel 10 (and the spacer member 40) is fitted into the groove portion 20b of the frame body 20 into which the sealant 30 is injected. In other words, the sealant 30 has no escape and hence the quantity thereof must be controlled if spacer members 40 are provided on both of the photoreceiving side and the rear side of the outer periphery 10a of the solar cell panel 10, while a clearance is disadvantageously formed between the solar cell panel 10 and the groove portion 20b if the quantity of the sealant 30 is insufficient. According to this embodiment, however, the surplus of the sealant 30 protrudes from the groove portion 20b on the rear side of the solar cell panel 10 so that no clearance is formed in the space between the groove portion 20b of the frame body 20 and the surface on the photoreceiving side of the solar cell panel 10, whereby the water resistance and the water stoppability of the thin film solar cell module 100 can be prevented from reduction.

According to this embodiment, as hereinabove described, the sealant 30 is charged up to the region corresponding to the position where the spacer member 40 is arranged on the rear side (surface of the back sheet 14) of the solar cell panel 10 so as to hold the solar cell panel 10 on a wider region, whereby the load resistance of the solar cell panel 10 can be improved.

According to this embodiment, as hereinabove described, the spacer member 40 is arranged on the region adjacent to the region where the solar cell layer 11 is arranged in plan view, whereby the spacer member 40, not arranged on a region overlapping the solar cell layer 11, does not block light incident upon the solar cell layer 11 but the region charged with the sealant 30 can be widened.

According to this embodiment, the frame body 20 is so formed as to enclose the outer periphery 10a of the solar cell panel 10 and the spacer member 40 is circumferentially arranged along the groove portion 20b of the frame body 20 in plan view as shown in FIG. 3 so that the body of the solar cell panel 10 can be uniformly held also in the circumferential direction (surface direction) of the solar cell panel 10, whereby the load resistance of the solar cell panel 10 can be uniformized also in the surface direction thereof.

According to this embodiment, the spacer member 40 is arranged on the overall periphery along the groove portion 20b of the frame body 20 in a substantially Pointless manner as shown in FIG. 3 so as to substantially come into contact with both of the portion around the outer periphery 10a on the photoreceiving side (side of the white plate glass layer 12) and the surface of the groove portion 20b of the frame body 20 along the overall periphery, whereby no rainwater or the like penetrates into the region of the sealant 30 filling up the space between the outer periphery 10a of the solar cell panel 10 and the groove portion 20b of the frame body 20 over the spacer member 40. Therefore, the water resistance and the water stoppability of the thin film solar cell module 100 can be further improved, in addition to the aforementioned effects.

According to this embodiment, as hereinabove described, the upper surface (photoreceiving surface) and the lower surface (rear surface) of the solar cell panel 10 and the surfaces of the groove portion 20b of the frame body 20 opposed to these upper and lower surfaces respectively are so formed as to be substantially parallel to each other so that force transmitted through the spacer member 40 and the sealant 30 is uniformized when a load is applied to the solar cell panel 10 due to bad weather conditions (strong wind etc.) in an outdoor location or the like, whereby the solar cell panel 10 can be prevented from concentration of a local load.

According to this embodiment, as hereinabove described, the sealant 30 is so charged as to enclose the surface (upper surface of the white plate glass layer 12) on the photoreceiving side of the solar cell panel 10, the surface (lower surface of the back sheet 14) on the rear side of the solar cell panel 10 and the end faces of the solar cell panel 10 for holding the outer periphery 10a of the solar cell panel 10 in an enclosing manner, whereby a load applied to the solar cell panel 10 due to bad weather conditions (strong wind etc.) in an outdoor location or the like can be reliably absorbed regardless of the direction of the load.

According to this embodiment, as hereinabove described, substantially the overall surface of the sealant 30, having the substantially U-shaped section, opposed to the groove portion 20b comes into contact with the inner surface of the groove portion 20b of the frame body 20 so that the contact area between the sealant 30 and the frame body 20 can be increased, thereby increasing an area where a load applied to the solar cell panel 10 due to bad weather conditions (strong wind etc.) in an outdoor location or the like can be dispersed to the frame body 20 through the sealant 30. Thus, the load applied to the solar cell panel 10 can be further dispersed.

According to this embodiment, as hereinabove described, the U-shaped sealant 30 is so arranged that the upper end face (photoreceiving side) is in contact with the spacer member 40 so that no clearance is formed between the spacer member 40 and the sealant 30, whereby rainwater or the like can be prevented from penetrating into the region between the spacer member 40 and the sealant 30. Thus, the water stoppability of the thin film solar cell module 100 can be further improved.

Although the present invention has been described and illustrated in detail, it is clearly understood that the same is by way of illustration and example only and is not to be taken by way of limitation, the spirit and scope of the present invention being limited only by the terms of the appended claims.

For example, while the aforementioned embodiment is applied to the thin film solar cell module 100 employing the unreinforced white plate glass layer 12, the present invention is not restricted to this but is also applicable to a crystalline solar cell module, for example, other than the thin film solar cell module using reinforced glass.

While the spacer member 40 is provided on the region between the outer periphery 10a on the side of the white plate glass layer 12 (photoreceiving side) of the solar cell panel 10 and the groove portion 20b of the frame body 20 opposed to the outer periphery 10a in the aforementioned embodiment, the present invention is not restricted to this but a spacer member 50 may alternatively be provided on the region between the outer periphery 10a on the side of the back sheet 14 (rear side) of the solar cell panel 10 and the groove portion 20b of the frame body 20 opposed to the outer periphery 10a, as in a first modification of the aforementioned embodiment shown in FIG. 8. The spacer member 50 is so formed as to have such a coefficient of elasticity that the same is not substantially deformed by the own weight of the solar cell panel 10. Also according to this structure of the first modification, the sealant 30 is so deformed and solidified as to have the same thickness as the spacer member 50 while filling up the space between the outer periphery 10a of the solar cell panel 10 and the groove portion 20b of the frame body 20, whereby the water resistance and the water stoppability of the thin film solar cell module 100 can be prevented from reduction. Further, the sealant 30 is so deformed and solidified that the thicknesses of the portions on the side of the spacer member 50 and the side opposite to the spacer member 50 are substantially identical to each other, to be capable of holding the solar cell panel 10 in substantially identical conditions regardless of the vertical direction. Thus, the load resistance of the solar cell panel 10 can be reliably improved. According to the first modification, the U-shaped sealant 30 is so arranged that the lower end face (rear side of the solar cell panel 10) thereof is in contact with the spacer member 50. The lower end face of the sealant 30 is an example of the “first end face” in the present invention.

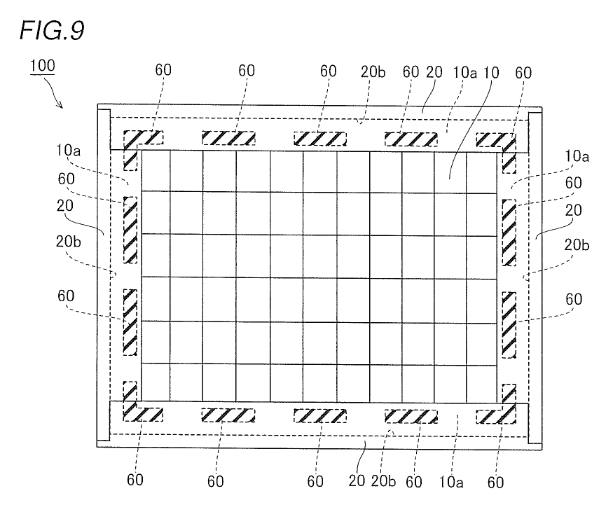

While the spacer member 40 is arranged on the overall periphery along the groove portion 20b of the frame body 20 in a substantially jointless manner in the aforementioned embodiment, the present invention is not restricted to this but spacer members 60 may alternatively be circumferentially arranged along the groove portion 20b of the frame member 20 at prescribed intervals, as in a second modification of the embodiment shown in FIG. 9. The spacer members 60 are examples of the “subspacer members” in the present invention. According to the second modification, the spacer members 60 are circumferentially arranged along the groove portion 20b of the frame member 20 at the prescribed intervals in plan view. In this case, a clearance may be provided at least partially between the spacer members 60 adjacent to each other.

While the spacer member 40 is previously mounted on the portion around the outer periphery 10a on the side of the white plate glass layer 12 and the solar cell panel 10 is fitted into the frame body 20 after injection of the sealant 30 in the manufacturing process for the thin film solar cell module 100 according to the aforementioned embodiment, the present invention is not restricted to this but the thin film solar cell module 100 may alternatively be manufactured by previously mounting the spacer member 40 on a prescribed region on the side of the groove portion 20b of the frame body 20 and fitting the solar cell panel 10 into the frame body 20 after injection of the sealant 30.

While the width of the spacer member 40 along arrow A (see FIG. 2) is set to about 2 mm in the aforementioned embodiment, the present invention is not restricted to this but the spacer member 40 may alternatively have a width smaller than the aforementioned width of about 2 mm so far as the spacer member 40 is not deformed in the thickness direction (along arrows B and C in FIG. 2) due to the own weight of the body of the solar cell panel 10 but can maintain the thickness of about 1.5 mm in assembling of the solar cell module 100 and the sealant 30 is so solidified as to have the same thickness as the spacer member 40 after the same is injected. For example, the width and the thickness of the spacer member 50 may be substantially equalized with each other so that the spacer member 50 has a substantially square sectional shape in a direction orthogonal to the extensional direction of the groove portion 20b, as in the first modification shown in FIG. 8.

What is claimed is:

1. A solar cell module comprising:
a platelike solar cell panel including a solar cell element;
a frame body including a groove portion into which the outer periphery of said solar cell panel is fitted;
a sealant so provided as to fill up a space between the outer periphery of said solar cell panel and said groove portion of said frame body; and
a spacer member, made of a material having a smaller coefficient of elasticity than the material for a photoreceiving side of said solar cell panel and the material for said frame body, provided on a region where said photoreceiving side or a rear side of the outer periphery of said solar cell panel and said groove portion of said frame body are opposed to each other.

2. The solar cell module according to claim 1, wherein
said spacer member is so arranged as to substantially come into contact with a portion around the outer periphery on said photoreceiving side or said rear side of said solar cell panel and a surface of said groove portion of said frame body opposed to said portion around the outer periphery on said photoreceiving side or said rear side of said solar cell panel.

3. The solar cell module according to claim 2, wherein
said spacer member is so arranged as to substantially come into contact with said portion around the outer periphery on said photoreceiving side of said solar cell panel and said surface of said groove portion of said frame body opposed to said portion around the outer periphery on said photoreceiving side of said solar cell panel.

4. The solar cell module according to claim 3, wherein
said spacer member is so provided as to fill up a space between a surface on said photoreceiving side of said solar cell panel and a surface of said groove portion of said frame body opposed to said surface on said photoreceiving side of said solar cell panel, and
said sealant is sealed by said spacer member on said photoreceiving side of said solar cell panel, and is so formed as to be exposed outward from said rear side of said solar cell panel where said spacer member is not arranged.

5. The solar cell module according to claim 4, wherein
said sealant is charged up to at least a region corresponding to the position where said spacer member is arranged on said rear side of said solar cell panel.

6. The solar cell module according to claim 4, wherein
said spacer member is arranged on a region outside the region where said solar cell element is arranged in plan view.

7. The solar cell module according to claim 6, wherein
said spacer member is arranged on a region adjacent to the region where said solar cell element is arranged in plan view.

8. The solar cell module according to claim 1, wherein
the thickness of a portion of said sealant filling up a space between a photoreceiving surface of said solar cell panel in the outer periphery of said solar cell panel and a surface of said groove portion of said frame body opposed to said photoreceiving surface and the thickness of another portion of said sealant filling up a space between a rear surface of said solar cell panel in the outer periphery of said solar cell panel and another surface of said groove portion of said frame body opposed to said rear surface are substantially identical to each other.

9. The solar cell module according to claim 1, wherein
said frame body is so formed as to enclose the outer periphery of said solar cell panel, and
said spacer member is circumferentially arranged along said groove portion of said frame body in plan view.

10. The solar cell module according to claim 9, wherein
said spacer member is arranged on the overall periphery along said groove portion of said frame body substantially in a jointless manner.

11. The solar cell module according to claim 9, wherein
said circumferentially arranged spacer member is formed by a plurality of subspacer members, and
a clearance is provided at least partially between said subspacer members adjacent to each other.

12. The solar cell module according to claim 11, wherein
said plurality of subspacer members are circumferentially arranged at a prescribed interval along said groove portion of said frame body in plan view.

13. The solar cell module according to claim 1, wherein
said spacer member is so formed as to have such a coefficient of elasticity that said spacer member is not substantially deformed by the own weight of said solar cell panel when arranged on said rear side of said solar cell panel.

14. The solar cell module according to claim 1, wherein
a photoreceiving surface and a rear surface of said solar cell panel and surfaces of said groove portion of said frame body opposed to said photoreceiving surface and said rear surface respectively are so formed as to be substantially parallel to each other.

15. The solar cell module according to claim 1, wherein
said sealant fills up said space between the outer periphery of said solar cell panel and said groove portion of said frame body to enclose a surface on said photoreceiving side of the outer periphery of said solar cell panel, another surface on said rear side of the outer periphery of said solar cell panel and end faces of said solar cell panel.

16. The solar cell module according to claim 1, wherein
the thickness of said spacer member is substantially equal to both of the interval between a surface on said photoreceiving side of said solar cell panel and a surface of said groove portion of said frame body opposed to said surface on said photoreceiving side of said solar cell panel and the interval between another surface on said rear side of said solar cell panel and another surface of said groove portion of said frame body opposed to said surface on said rear side of said solar cell panel.

17. The solar cell module according to claim 1, wherein
said spacer member is arranged on a region of said groove portion inward beyond an opening end face of said groove portion.

18. The solar cell module according to claim 1, wherein
a section of said spacer member in a direction orthogonal to the extensional direction of said groove portion is so formed as to have a substantially square shape.

19. The solar cell module according to claim 1, wherein
said sealant is so formed as to have a U-shaped sectional shape along the inner surface of said groove portion of said frame body in a direction orthogonal to the extensional direction of said groove portion, and
substantially the overall surface of said U-shaped sealant opposed to said groove portion is in contact with the inner surface of said groove portion of said frame body.

20. The solar cell module according to claim 19, wherein
said U-shaped sealant has a first end face and a second end face, and
said first end face of said U-shaped sealant is so arranged as to come into contact with said spacer member.
